(19) United States
(12) Patent Application Publication
(10) Pub. No.: US 2023/0025295 A1
(43) Pub. Date: Jan. 26, 2023

(54) WIRING SUBSTRATE, METHOD OF FABRICATING THE SAME, AND METHOD OF FABRICATING SEMICONDUCTOR PACKAGE INCLUDING THE SAME

(71) Applicant: Samsung Electronics Co., Ltd., Suwon-si (KR)

(72) Inventor: SUNNYEONG JUNG, Asan-si (KR)

(21) Appl. No.: 17/827,751

(22) Filed: May 29, 2022

(30) Foreign Application Priority Data
Jul. 21, 2021 (KR) 10-2021-0095448

(51) Int. Cl. H01L 23/498; H01L 21/48; H01L 21/56

(52) U.S. Cl. CPC H01L 23/49894; H01L 21/486; H01L 21/481; H01L 21/561; H01L 21/566; H01L 24/16

(57) ABSTRACT

Disclosed are wiring substrates, methods of fabricating the same, and methods of fabricating semiconductor packages. The wiring substrate includes a dielectric layer that includes a plurality of unit regions, a sawing region that surrounds each of the unit regions, and an edge region that surrounds the unit regions and the sawing region, a first upper protection pattern on a top surface of the dielectric layer on the unit regions and the sawing region, and a second upper protection pattern on a top surface of the dielectric layer on the edge region. The second upper protection pattern surrounds the first upper protection pattern when viewed in plan and includes a dielectric material different from a dielectric material of the first upper protection pattern.

### CROSS-REFERENCE TO RELATED APPLICATION(S)

This U.S. nonprovisional application claims priority under 35 U.S.C § 119 to Korean Patent Application No. 10-2021-0095448 filed on Jul. 21, 2021 in the Korean Intellectual Property Office, the disclosure of which is hereby incorporated by reference in its entirety.

### BACKGROUND

The present inventive concepts relate to a wiring substrate, a method of fabricating the same, and a method of fabricating a semiconductor package including the same.

Portable devices have been increasingly demanded in recent electronic product markets, and as a result, it has been ceaselessly required for reduction in size and weight of electronic parts mounted on the portable devices.

With the requirement of high functionality, rapid speed, and compact size of electronic products, a wiring substrate on which a semiconductor chip is mounted also needs fine circuitry, excellent electrical properties, increased reliability, high-speed transfer structure, and high functionality.

### SUMMARY

Some embodiments of the present inventive concepts provide a wiring substrate with increased reliability and a method of fabricating the same.

Some embodiments of the present inventive concepts provide a method of fabricating a semiconductor package, which method is capable of reducing process defects.

The object of the present inventive concepts is not limited to the mentioned above, and other objects which have not been mentioned above will be clearly understood to those skilled in the art from the following description.

According to some embodiments of the present inventive concepts, a wiring substrate may include a dielectric layer that includes a plurality of unit regions, a sawing region that surrounds each of the unit regions, and an edge region that surrounds the unit regions and the sawing region; a first upper protection pattern on a top surface of the dielectric layer on the unit regions and the sawing region; and a second upper protection pattern on a top surface of the dielectric layer on the edge region. The second upper protection pattern may surround the first upper protection pattern when viewed in plan and include a dielectric material different from a dielectric material of the first upper protection pattern.

According to some embodiments of the present inventive concepts, a method of fabricating a wiring substrate may include providing a panel substrate that includes a plurality of substrate regions and a cutting region that surrounds each of the substrate regions; forming a first upper protection layer on a top surface of the panel substrate; patterning the first upper protection layer to form an opening that exposes the top surface of the panel substrate on the cutting region; forming a second upper protection pattern in the opening; and forming a wiring substrate by cutting the panel substrate along the cutting region to separate the substrate regions from each other. The second upper protection pattern may include a dielectric material different from a dielectric material of the first upper protection layer.

According to some embodiments of the present inventive concepts, a method of fabricating a semiconductor package may include providing a wiring substrate that has a plurality of unit regions, a sawing region that surrounds each of the unit regions, and an edge region that surrounds the unit regions and the sawing region; mounting a plurality of semiconductor chips on corresponding unit regions of the wiring substrate; forming on the wiring substrate a molding layer that covers the semiconductor chips; and after forming the molding layer, cutting the wiring substrate along the sawing region to separate the unit regions from each other on which the semiconductor chips are mounted. The wiring substrate may include forming a first upper protection pattern that covers the unit regions and the sawing region, and forming a second upper protection pattern that surrounds the first upper protection pattern on the edge region. The forming of the molding layer may include providing a cavity with the wiring substrate on which the semiconductor chips are mounted, the cavity being defined by an upper mold and a lower mold; attaching a release film that covers a surface of the upper mold and contacts the second upper protection pattern of the wiring substrate; and introducing a molding resin into the cavity.

Details of other embodiments are included in the description and drawings.

### BRIEF DESCRIPTION OF THE DRAWINGS

FIG. 1 illustrates a flow chart showing a method of fabricating a wiring substrate according to some embodiments of the present inventive concepts.

FIGS. 2A to 5A illustrate plan views showing a method of fabricating a wiring substrate according to some embodiments of the present inventive concepts.

FIGS. 2B to 5B illustrate cross-sectional views taken along line I-I′ of FIGS. 2A to 5A, showing a method of fabricating a wiring substrate according to some embodiments of the present inventive concepts.

FIGS. 6A and 6B illustrate enlarged views showing section P of FIG. 5B according to example embodiments.

FIG. 7 illustrates a flow chart showing a method of fabricating a semiconductor package by using a wiring substrate according to some embodiments of the present inventive concepts.

FIGS. 8 to 11 illustrate cross-sectional views showing a method of fabricating a semiconductor package by using a wiring substrate according to some embodiments of the present inventive concepts.

### DETAILED DESCRIPTION

It will be discussed hereinafter a method of fabricating a wiring substrate and a method of fabricating a semiconductor package according to some embodiments of the present inventive concepts in conjunction with the accompanying drawings.

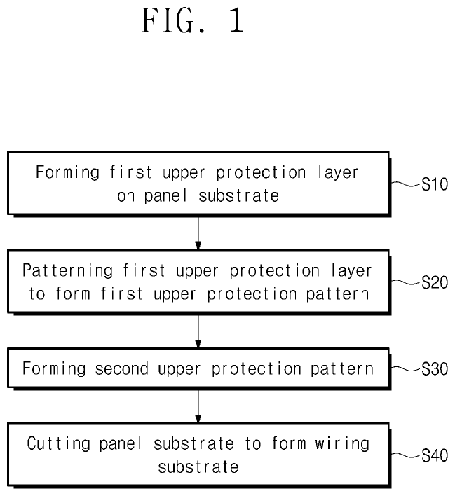

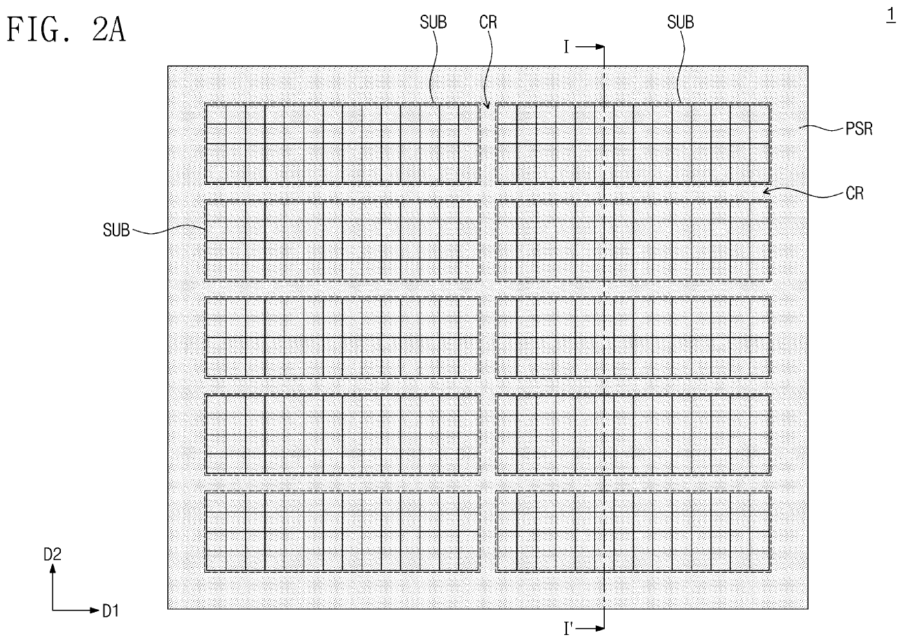

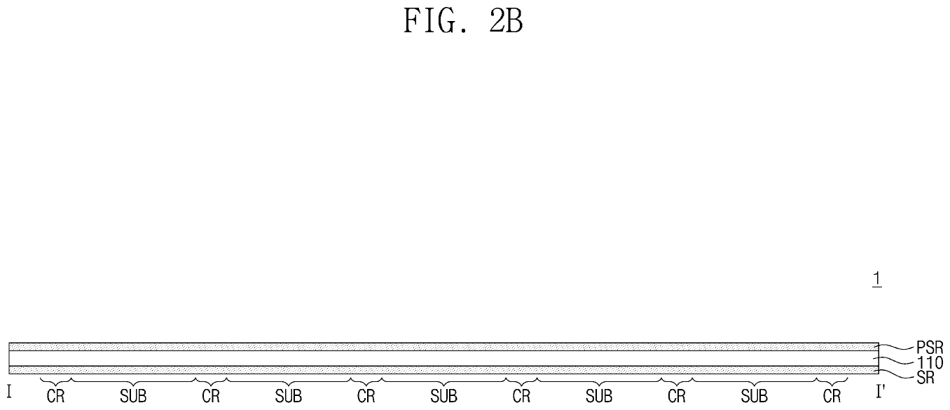

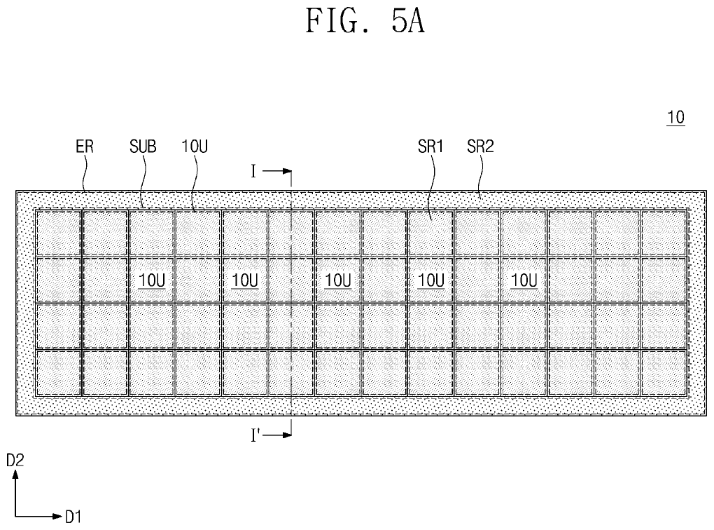

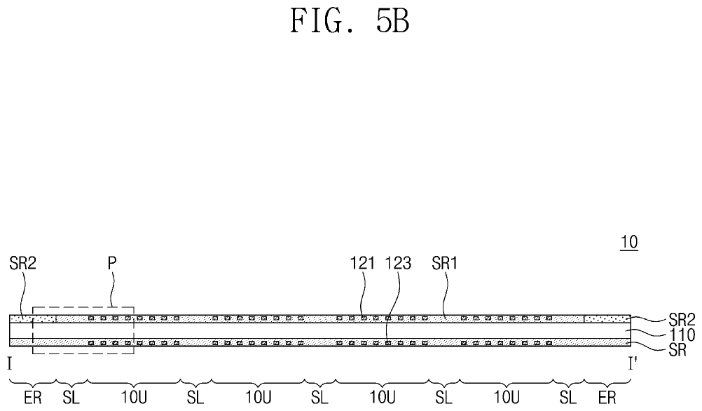

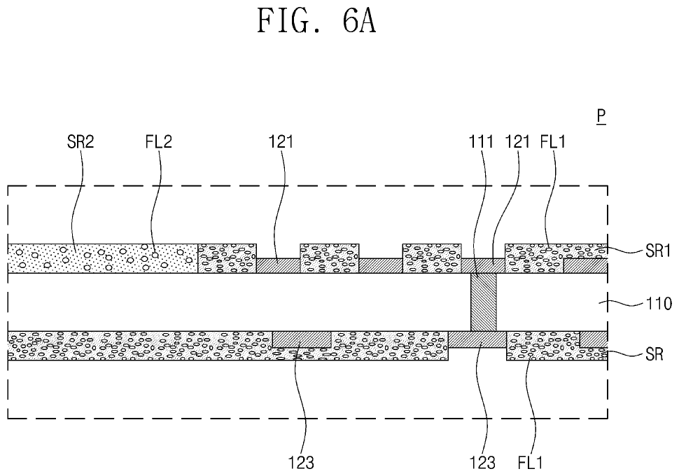

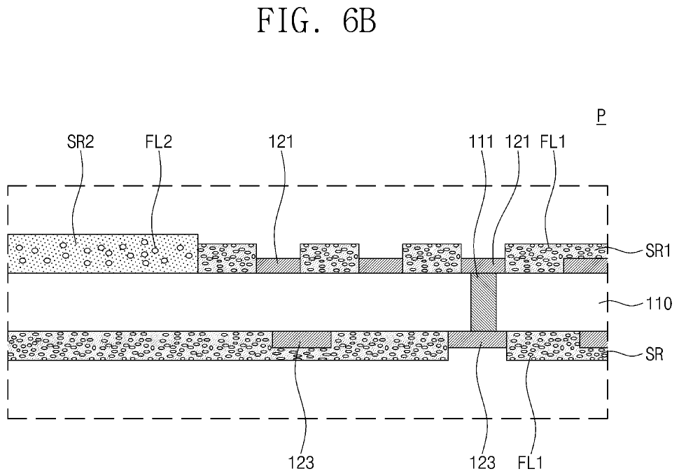

FIG. 1 illustrates a flow chart showing a method of fabricating a wiring substrate according to some embodiments of the present inventive concepts. FIGS. 2A to 5A illustrate plan views showing a method of fabricating a wiring substrate according to some embodiments of the present inventive concepts. FIGS. 2B to 5B illustrate cross-sectional views taken along line I-I′ of FIGS. 2A to 5A, showing a method of fabricating a wiring substrate according to some embodiments of the present inventive concepts. FIGS. 6A and 6B illustrate enlarged views showing section P of FIG. 5B.

Referring to FIGS. 1, 2A, and 2B, a panel substrate 1 may be provided which includes a plurality of substrate regions SUB and a cutting region CR.

The substrate regions SUB may be two-dimensionally arranged along a first direction D1 and a second direction D2 that are orthogonal to each other. In some embodiments, the panel substrate 1 may have a rectangular shape, and the number of the substrate regions SUB arranged along the first direction D1 may be different from that of the substrate regions SUB arranged along the second direction D2. The substrate regions SUB may be arranged spaced apart from each other at a regular interval. For example, an interval in the first direction D1 between the substrate regions SUB may be substantially the same as that in the second direction D2 between the substrate regions SUB.

The cutting region CR may surround each of the substrate regions SUB. A portion of the cutting region CR may be provided between the substrate regions SUB. The cutting region CR may include first sections that extend in the first direction D1 between the substrate regions SUB that are adjacent to each other in the second direction D2, and may also include second sections that extend in the second direction D2 between the substrate regions SUB that are adjacent to each other in the first direction D1. In this case, the first sections may be spaced apart from each other in the second direction D2, and the second sections may be spaced apart from each other in the first direction D1.

The panel substrate 1 may include a dielectric layer 110, upper wire patterns (see 121 of FIG. 5B), and lower wire patterns (see 123 of FIG. 5B).

The dielectric layer 110 may have a top surface and a bottom surface that are opposite to each other, and may include a single or plurality of dielectric layers.

The dielectric layer 110 may include or be formed of a dielectric material such as resin, and may have a thin plate shape. The resin of the dielectric layer 110 may be a thermosetting resin, a thermoplastic resin, or any other suitable material. For example, the dielectric layer 110 may be epoxy resin or polyimide. The epoxy resin may be, for example, naphthalene epoxy resin, bisphenol A type epoxy resin, bisphenol F type epoxy resin, novolac epoxy resin, cresol novolac resin, rubber modified resin, cyclic aliphatic epoxy resin, silicone epoxy resin, nitrogen epoxy resin, or phosphorus epoxy resin, but the present inventive concepts are not limited thereto. Alternatively, the dielectric layer 110 may include prepreg, Ajinomoto build-up film (ABF), flame retardant 4 (FR-4), or bismaleimide triazine (BT). In some embodiments, the dielectric layer 110 may have a thickness of about 20 μm to about 100 μm. The term such as “about” may reflect amounts, sizes, orientations, or layouts that vary only in a small relative manner, and/or in a way that does not significantly alter the operation, functionality, or structure of certain elements. For example, a range from “about 0.1 to about 1” may encompass a range such as a 0% to 5% deviation around 0.1 and a 0% to 5% deviation around 1, especially if such deviation maintains the same effect as the listed range.

On each of the substrate regions SUB, the upper wire patterns (see 121 of FIG. 5B) may be provided on the top surface of the dielectric layer 110, and the lower wire patterns (see 123 of FIG. 5B) may be provided on the bottom surface of the dielectric layer 110.

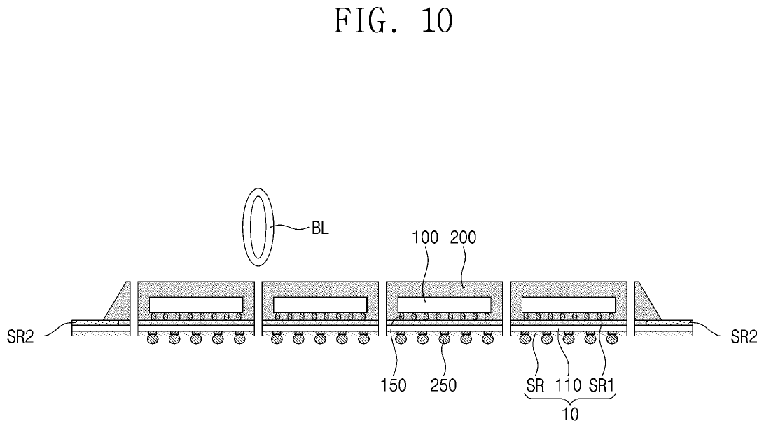

The upper and lower wire patterns (see 121 and 123 of FIG. 5B) on the top and bottom surfaces of the dielectric layer 110 may be spaced apart from the cutting region CR. The upper wire patterns (see 121 of FIG. 5B) may be used as connection patterns for redistribution of semiconductor chips mounted on the substrate regions SUB. The lower wire patterns (see 123 of FIG. 5B) may be used as connection patterns to which external coupling terminals are attached. The upper wire patterns (see 121 of FIG. 5B) may be electrically connected to the lower wire patterns (see 123 of FIG. 5B) through vias (see 111 of FIGS. 6A and 6B) that penetrate the dielectric layer 110. Although not shown, other conductive lines may be provided on the top and bottom surfaces of the dielectric layer 110 to transfer signals between an external device and a semiconductor chip (see FIG. 10).

Each of the upper and lower wire patterns (see 121 and 123 of FIG. 5B) may include at least one selected from copper (Cu), aluminum (Al), silver (Ag), tin (Sn), gold (Au), nickel (Ni), lead (Pb), titanium (Ti), and any combination thereof.

A first upper protection layer PSR may be formed on the panel substrate 1 (S10).

The first upper protection layer PSR may cover an entire top surface of the panel substrate 1. The first upper protection layer PSR may cover the upper wire patterns (see 121 of FIG. 5B). The first upper protection layer PSR may expose a portion of the upper wire patterns (see 121 of FIG. 5B).

The first upper protection layer PSR may include or be formed of a dielectric material, such as solder resist. The solder resist may include polymer or resin, but the present inventive concepts are not limited thereto. The first upper protection layer PSR may have a thickness of about 10 μm to about 20 μm.

The first upper protection layer PSR may include first fillers. The first fillers may include silicon oxide, such as amorphous silicon oxide (SiO₂) or crystalline silicon oxide (SiO₂). Alternatively, the first fillers may include at least one selected from aluminum oxide (Al₂O₃), magnesium oxide (MgO), zinc oxide (ZnO), silicon carbide (SiC), aluminum nitride (AlN), beryllium oxide (BeO), and boron nitride (BN).

The first upper protection layer PSR may be formed by coating or depositing on the top surface of the dielectric layer 110 a precursor material in which the first fillers are mixed in the dielectric material, and then curing the dielectric material. Alternatively, the first upper protection layer PSR may be formed by coating or depositing a dielectric material on the top surface of the dielectric layer 110, providing the dielectric material with the first fillers, and then curing the dielectric material.

The first fillers in the first upper protection layer PSR may be provided to about 1% to about 70% volume faction relative to the dielectric material in the first upper protection layer PSR. The first upper protection layer PSR may include solder resist, and the first fillers may include silicon oxide.

A lower protection layer SR may be formed on a bottom surface of the panel substrate 1. The lower protection layer SR may cover the lower wire patterns (see 123 of FIG. 5). The lower protection layer SR may expose a portion of the lower wire patterns (see 123 of FIG. 5).

The lower protection layer SR may include a dielectric material, such as solder resist. The lower protection layer SR may include fillers. The fillers may include silicon oxide, such as amorphous silicon oxide (SiO₂) or crystalline silicon oxide (SiO₂).

The lower protection layer SR may include or be formed of the same material as that of the first upper protection layer PSR. The lower protection layer SR may have a thickness of about 10 μm to about 20 μm.

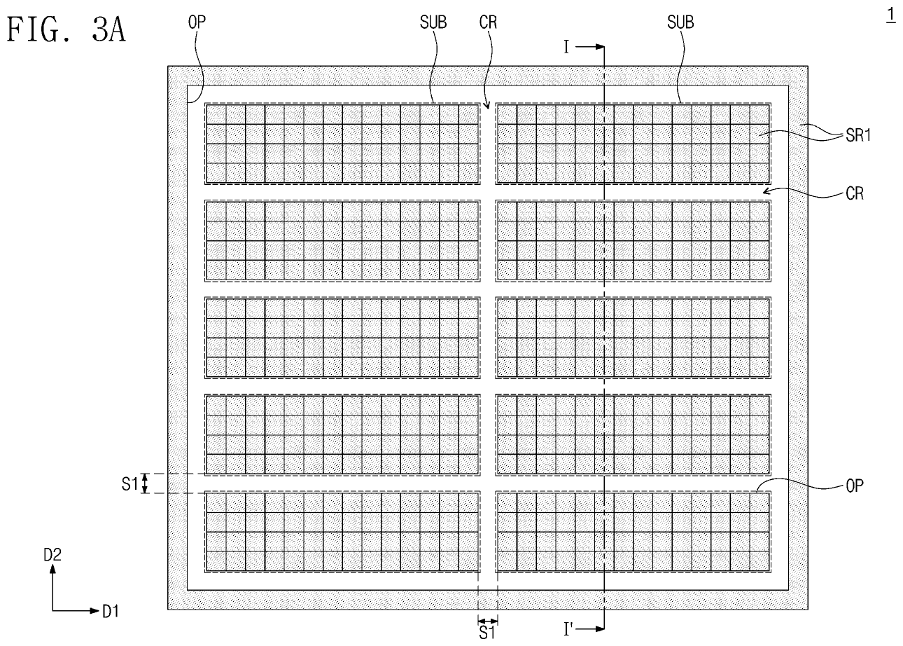

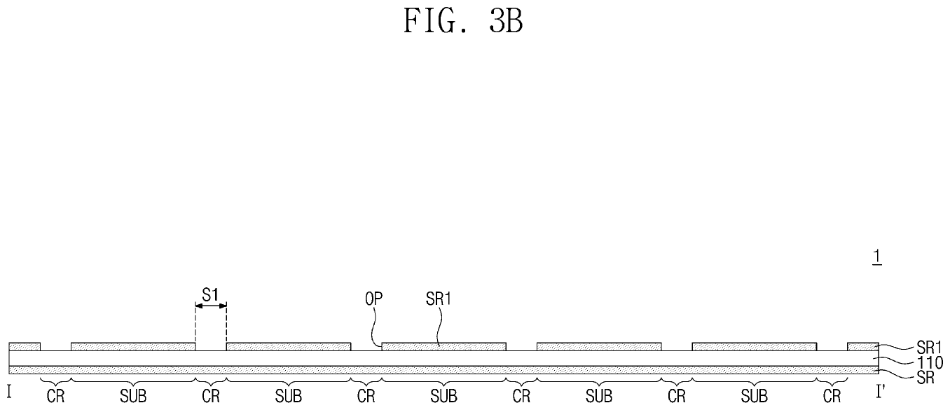

Referring to FIGS. 1, 3A, and 3B, the panel substrate 1 may undergo a patterning process of the first upper protection layer PSR to form an opening OP that exposes the dielectric layer 110 on the cutting region CR (S20).

As the opening OP is formed in the first upper protection layer PSR, first upper patterns SR1 may be formed to correspondingly cover the substrate regions SUB.

The first upper protection patterns SR1 may expose the dielectric layer 110 on the cutting region CR. When forming the first upper protection patterns SR1, openings (not shown) may be formed to partially expose the upper wire patterns 121 on each substrate region SUB.

A mask that covers the substrate regions SUB may be used to perform an exposure process on the first upper protection layer PSR, and then the first upper protection layer PSR may undergo a development process to remove the first upper protection layer PSR from the cutting region CR, with the result that the first upper protection patterns SR1 may be formed.

The first upper protection patterns SR1 may be spaced apart from each other in the first direction D1 and the second direction D2, and an interval 51 in the first direction D1 may be substantially the same as an interval 51 in the second direction D2.

A range of about 5 mm to about 20 mm may be given as the interval 51 in the first or second direction D1 or D2 of the first upper protection patterns SR1. For example, the opening OP defined by the first upper protection patterns SR1 may have a width of about 5 mm to about 20 mm in the first direction D1 or in the second direction D2.

After the formation of the first upper protection patterns SR1, the lower protection layer SR may undergo photolithography and development processes to form openings (not shown) that expose portions of the lower wire patterns (see 123 of FIG. 5B) on each substrate region SUB.

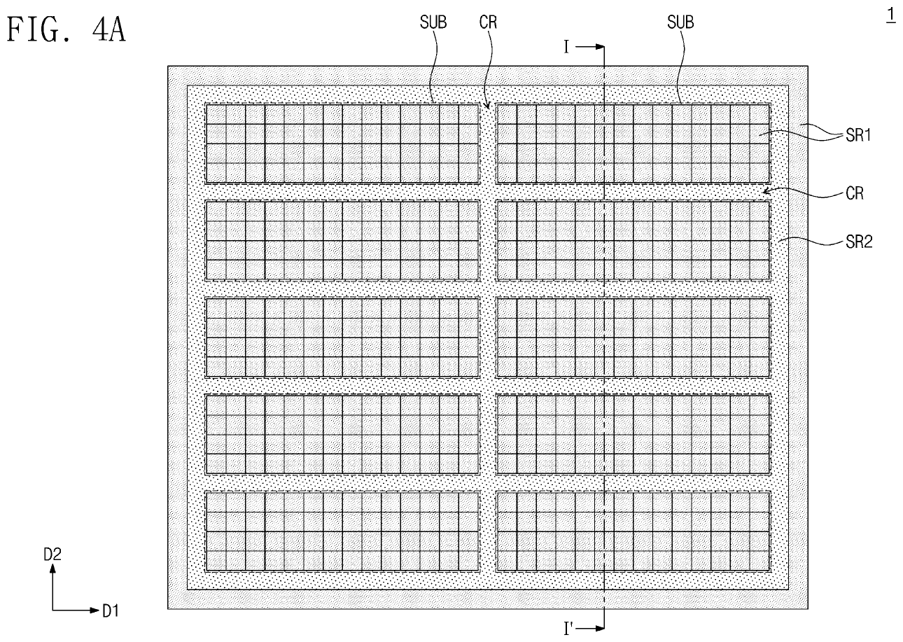

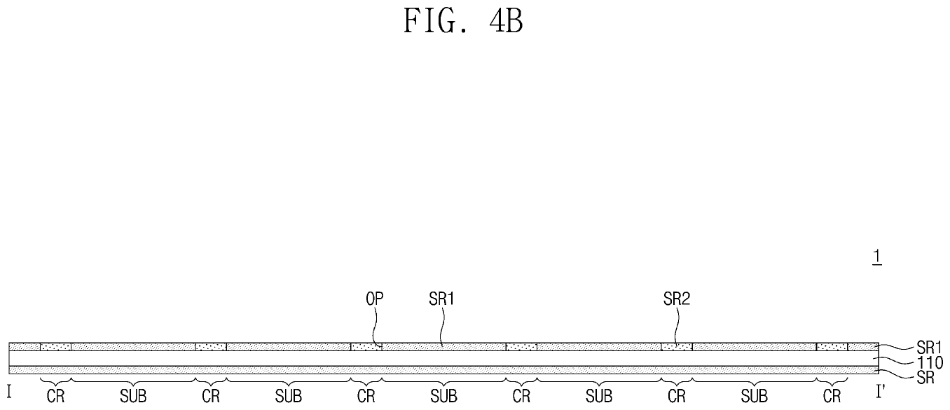

Referring to FIGS. 1, 4A, and 4B, the panel substrate 1 may undergo a forming process of a second upper protection pattern SR2.

The second upper protection pattern SR2 may be formed on the cutting region CR (S30).

The second upper protection pattern SR2 may be formed in the opening OP defined by the first upper protection patterns SR1. The second upper protection pattern SR2 may include or be formed of a material whose adhesive force is less than that of the first upper protection patterns SR1. The second upper protection pattern SR2 may surround each of the first upper protection patterns SR1.

The second upper protection pattern SR2 may be in contact with sidewalls of the first upper protection patterns SR1. The second upper protection pattern SR2 may have a width of about 5 mm to about 20 mm in the first direction D1 or in the second direction D2. The second upper protection pattern SR2 may have a thickness of about 10 μm to about 20 μm. It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element, there are no intervening elements present at the point of contact.

The second upper protection pattern SR2 may be formed by coating a precursor material in which second fillers are mixed in a dielectric material. The second upper protection pattern SR2 may include or be formed of the same material as that of the first upper protection patterns SR1. The second upper protection pattern SR2 may include a dielectric material, such as solder resist.

The second fillers may be a material the same as or different from that of the first fillers. The second fillers may include silicon oxide, such as amorphous silicon oxide (SiO₂) or crystalline silicon oxide (SiO₂). Alternatively, the second fillers may include at least one selected from aluminum oxide (Al₂O₃), magnesium oxide (MgO), zinc oxide (ZnO), silicon carbide (SiC), aluminum nitride (AlN), beryllium oxide (BeO), and boron nitride (BN).

The adhesive force of the second upper protection pattern SR2 may depend on a content or size of the second fillers. In some embodiments, the content of the second fillers in the second upper protection pattern SR2 may be less than that of the first fillers in each of the first upper protection patterns SR1. The second fillers in the second upper protection pattern SR2 may be provided to about 1% to about 50% volume faction relative to the dielectric material in the second upper protection pattern SR2.

The second upper protection pattern SR2 may be coated by using a rubber squeegee, a doctor blade, a dispenser, or an inkjet. For example, the second upper protection pattern SR2 may be formed by using a squeegee to coat a solder resist. The squeegee may be a tool to press and spread a solder resist supplied on the dielectric layer 110 on the cutting region CR, while contacting a surface of the first upper protection pattern SR1. Herein, for convenience of description, the terms of the first upper protection pattern SR1 and the first upper protection patterns SR1 may be used interchangeably.

The second upper protection pattern SR2 may be formed by squeegee coating and thus the second upper protection pattern SR2 may have a top surface substantially coplanar with those of the first upper protection patterns SR1.

Referring to FIGS. 1, 5A, and 5B, the panel substrate 1 may undergo a cutting process to form wiring substrates 10 (S40).

The substrate regions SUB of the dielectric layer 110 may separate from each other in the cutting process. A blade may be employed to perform the cutting process on the panel substrate 1, but the present inventive concepts are not limited thereto. The blade may be used such that the second upper protection pattern SR2, the dielectric layer 110, and the lower protection layer SR may be cut along the cutting region CR. The cutting process may eventually remove components on the cutting region CR. The upper and lower wire patterns 121 and 123 on the substrate regions SUB may not be exposed to the cutting process.

A wiring substrate 10 formed by a fabrication method according to some embodiments of the present inventive concepts may include a single substrate region SUB and an edge region ER that surrounds the substrate region SUB. The edge region ER of the wiring substrate 10 may correspond to the cutting region CR of the panel substrate 1. For example, the edge region ER of the wiring substrate 10 may be a portion of the cutting region CR of the panel substrate 1. The edge region ER of the wiring substrate 10 in the first and second direction D1 or D2 may have a width less than that of the cutting region CR of the panel substrate 1 in the first and second direction D1 or D2.

For the wiring substrate 10, the substrate region SUB may include a plurality of unit regions 10U and a sawing region SL that surrounds each of the unit regions 10U.

For example, referring to FIG. 6A, the wiring substrate 10 may include a dielectric layer 110, upper wire patterns 121, lower wire patterns 123, vias 111, a first upper protection pattern SR1, and a second upper protection pattern SR2. Although not shown, the wiring substrate 10 may include other conductive lines in the dielectric layer 110 on each of the unit regions 10U.

The first and second upper protection patterns SR1 and SR2 may include or be formed of different materials from each other. The first and second upper protection patterns SR1 and SR2 may include or be formed of different dielectric materials whose adhesive forces are different from each other.

The first upper protection pattern SR1 may be a first solder resist layer including first fillers FL1. The second upper protection pattern SR2 may be a second solder resist layer including second fillers FL2.

The first fillers FL1 may include silicon oxide, such as amorphous silicon oxide (SiO₂) or crystalline silicon oxide (SiO₂). Alternatively, the first fillers FL1 may include at least one selected from aluminum oxide (Al₂O₃), magnesium oxide (MgO), zinc oxide (ZnO), silicon carbide (SiC), aluminum nitride (AlN), beryllium oxide (BeO), and boron nitride (BN).

For example, the second fillers FL2 may include or be formed of the same material as that of the first fillers FL1. For another example, the second fillers FL2 may include or be formed of a different material from that of the first fillers FL1. In this case, the first fillers FL1 may have a size different from that of the second fillers FL2.

In some embodiments, a content of the second fillers FL2 in the second upper protection pattern SR2 may be less than that of the first fillers FL1 in the first upper protection patterns SR1. The first fillers FL1 in the first upper protection pattern SR1 may be provided to about 1% to about 70% volume faction relative to the dielectric material in the first upper protection pattern SR1. The second fillers FL2 in the second upper protection pattern SR2 may be provided to about 1% to about 50% volume faction relative to the dielectric material in the second upper protection pattern SR2.

The first fillers FL1 in the first upper protection pattern SR1 exposed to a surface of the first upper protection pattern SR1 may be greater than the second fillers FL2 in the second upper protection pattern SR2 exposed to a surface of the second upper protection pattern SR2, and thus the first upper protection pattern SR1 may have an adhesive force greater than that of the second upper protection pattern SR2. The second fillers FL2 in the second upper protection pattern SR2 may be dispersed in the solder resist, and thus may not be easily exposed to a surface of the second upper protection pattern SR2. The first upper protection pattern SR1 may have a surface roughness greater than that of the second upper protection pattern SR2.

The first upper protection pattern SR1 may expose top surfaces of some of the upper wire patterns 121 and may cover top surfaces of others of the upper wire patterns 121. The first upper protection pattern SR1 may have a thickness greater than those of the upper wire patterns 121.

The second upper protection pattern SR2 may have a thickness the same as that of the first upper protection pattern SR1. For example, the second upper protection pattern SR2 may have a top surface coplanar with that of the first upper protection pattern SR1.

Alternatively, the second upper protection pattern SR2 may have a thickness different from that of the first upper protection pattern SR1. For example, as shown in FIG. 6B, the thickness of the second upper protection pattern SR2 may be greater than that of the first upper protection pattern SR1.

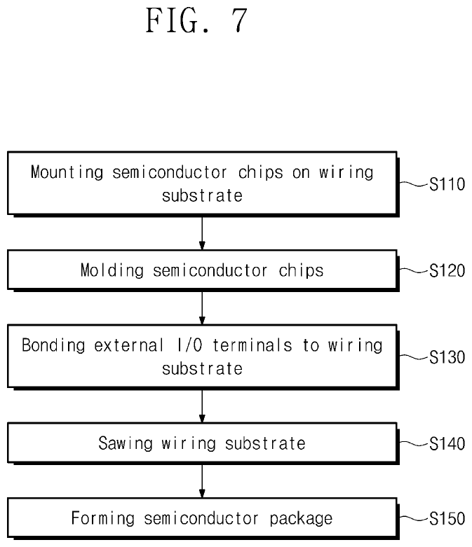

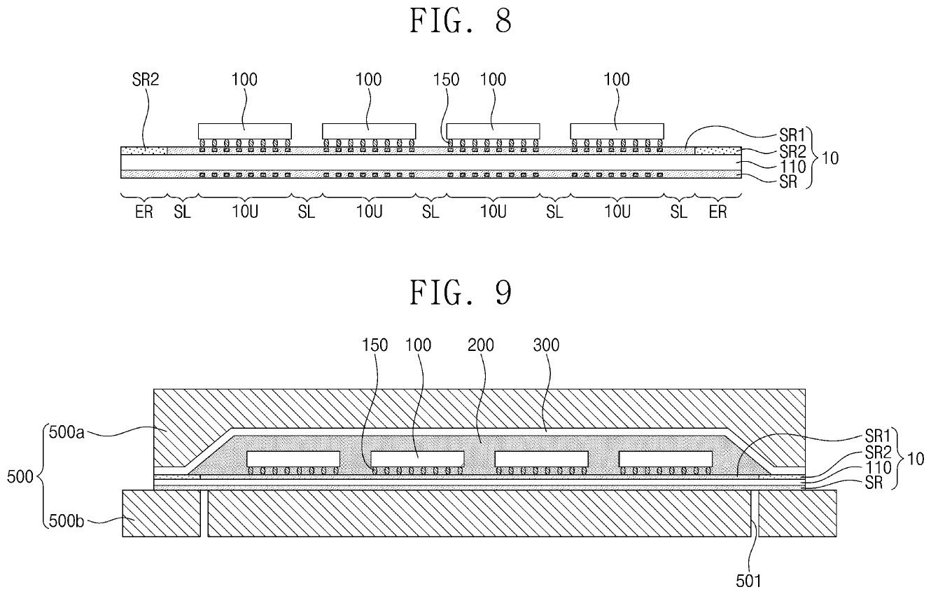

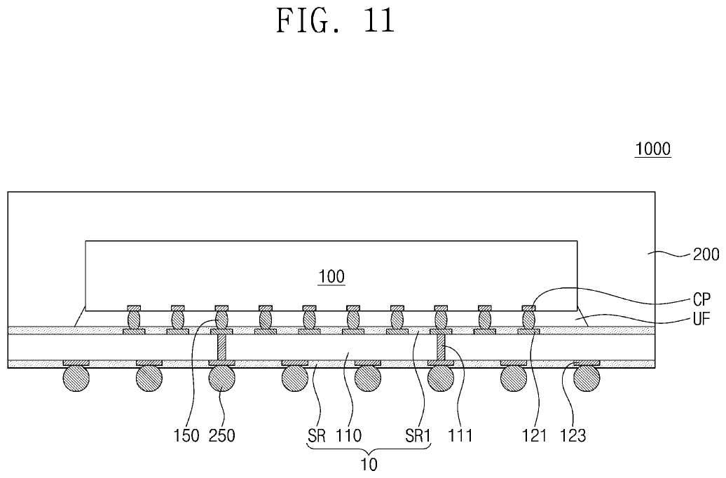

FIG. 7 illustrates a flow chart showing a method of fabricating a semiconductor package by using a wiring substrate according to some embodiments of the present inventive concepts. FIGS. 8 to 11 illustrate cross-sectional views showing a method of fabricating a semiconductor package by using a wiring substrate according to some embodiments of the present inventive concepts.

The same technical features as those of the embodiments discussed above may be omitted in the interest of brevity of description.

Referring to FIGS. 5A, 7, and 8, semiconductor chips 100 may be mounted on the wiring substrate 10 that is fabricated by the aforementioned embodiments of the present inventive concepts (S110).

The wiring substrate 10 may include a plurality of unit regions 10U, a sawing region SL that surrounds each of the unit regions 10U, and an edge region ER that surrounds the unit regions 10U and the sawing region SL. The wiring substrate 10 may include a dielectric layer 110, a first upper protection pattern SR1, a second upper protection pattern SR2, and a lower protection layer SR. The wiring substrate 10 may include upper and lower wire patterns (see 121 and 123 of FIG. 5B) on each of the unit regions 10U.

The upper wire patterns 121 of the wiring substrate 10 may be provided as under bump pads that are formed to connect connection terminals 150. The semiconductor chip 100 may be coupled through the connection terminals 150 to the under bump pads. Herein, for convenience of description, the terms of the semiconductor chip 100 and the semiconductor chips 100 may be used interchangeably. The connection terminals 150 may be solder balls formed of one or more of tin, lead, and copper.

An under fill layer may fill spaces between the semiconductor chips 100 and the first upper protection pattern SR1. The under fill layer may fill gaps between the connection terminals 150. The under fill layer may include a thermo-curable resin or a photo-curable resin. The under fill layer may further include inorganic fillers or organic fillers. Alternatively, the under fill layer may be omitted, and in this case, a molding layer may fill spaces between the wiring substrate 10 and bottom surfaces of the semiconductor chips 100.

Referring to FIGS. 5A, 7, and 9, a molding apparatus 500 may receive therein the wiring substrate 10 on which the semiconductor chips 100 are mounted, and a molding process may be performed to mold the semiconductor chips 100 (S120).

The molding apparatus 500 may include an upper mold 500a, a lower mold 500b, and a vacuum suction line (not shown).

The upper mold 500a may include a recess part filled with a molding resin and an edge part around the recess part. The edge region ER of the wiring substrate 10 may be located between the lower mold 500b and the edge part of the upper mold 500a, and the semiconductor chips 100 may be positioned in the recess part of the upper mold 500a.

The upper and lower molds 500a and 500b may be combined with each other to form a cavity in the molding apparatus 500. The cavity may provide the molding apparatus 500 with a space into which a molding resin is introduced. The cavity may have an appropriate size and shape that correspond to those of the wiring substrate 10.

Before combining the upper mold 500a with the lower mold 500b, a release film 300 may be attached to the upper mold 500a. The release film 300 may be attached to face the lower mold 500b. An edge portion of the release film 300 may be in contact with the top surface of the second upper protection pattern SR2 of the wiring substrate 10.

The release film 300 may include a material that is stable without being deformed at temperatures of a molding process. The release film 300 may include polytetrafluoroethylene (PTEE) or ethylene/tetrafluoroethylene copolymer (ETFE).

The lower mold 500b may include vacuum holes 501, and the wiring substrate 10 may be adsorbed and fixed through the vacuum holes 501 to the lower mold 500b.

A molding resin may enter the cavity to flow onto an entirety of the wiring substrate 10, and thus a molding layer 200 may be formed to fill spaces between the wiring substrate 10 and the semiconductor chips 100 and to cover the semiconductor chips 100. The molding layer 200 may be in contact with the top surface of the first upper protection pattern SR1.

For example, the molding resin may include a dielectric polymer material, such as epoxy molding compound. Selectively, the molding resin may include various encapsulation materials other than that discussed above. For example, the molding resin may be an epoxy-based material with which filler particles are mixed. For example, the filler particles may include silica or alumina.

The cavity may receive therein the molding resin to form the molding layer 200, and then the upper mold 500a and the lower mold 500b may be separated from each other. In this stage, the release film 300 may facilitate separation of the molding layer 200 from the upper mold 500a.

When the upper mold 500a and the lower mold 500b are separated from each other, the release film 300 may be first detached from the second upper protection pattern SR2, whose adhesive force is low, on the edge region ER, and thus the release film 300 may be prevented from being adhered to the wiring substrate 10 when the upper mold 500a is opened. In addition, the wiring substrate 10 may be prevented from detachment from the vacuum holes 501 of the lower mold 500b, which detachment is caused by attachment of the release film 300 to the wiring substrate 10. For example, it may be possible to prevent defects such as deformation or warpage of the wiring substrate 10 during the molding process.

Referring to FIGS. 5A, 7, and 10, after the formation of the molding layer 200, external input/output terminals 250 may be bonded to a bottom surface of the wiring substrate 10 (S130).

The external input/output terminals 250 may be attached to the lower wire patterns 123 on each of the unit regions 10U. The external input/output terminals 250 may be solder balls or bumps. The external input/output terminals 250 may be coupled to internal lines, such as the upper and lower wire patterns 121 and 123, the vias 111, and other conductive lines, of the wiring substrate 10 and may be electrically connected to the semiconductor chips 100. For example, electrical signals provided from an external electronic apparatus may be provided to the semiconductor chips 100 through the external input/output terminals 250 and the internal lines.

The wiring substrate 10 may undergo a sawing process performed along the sawing region SL (S140). Therefore, the unit regions 10U on which the semiconductor chips 100 are disposed may be individually separated from each other.

In the sawing process, a sawing apparatus may be used such that the wiring substrate 10 and the molding layer 200 between the unit regions 10U may be diced to cause the molded semiconductor chips 100 to separate from each other. In this case, a sawing blade BL or a laser may be employed in the sawing process.

The sawing process may remove the edge region ER of the wiring substrate 10. Therefore, the first upper protection pattern SR1 may selectively remain on the wiring substrate 10 of a semiconductor package 1000 which will be discussed below.

Referring to FIGS. 5A, 7, and 11, a semiconductor package 1000 fabricated according to some embodiments of the present inventive concepts may include the wiring substrate 10, the semiconductor chip 100, and the molding layer 200 (S150).

The wiring substrate 10 of the semiconductor package 1000 may include the dielectric layer 110, the vias 111, the upper wire patterns 121, the lower wire patterns 123, the first upper protection pattern SR1, and the lower protection layer SR.

The semiconductor chip 100 may be provided on the wiring substrate 10. When viewed in plan, the semiconductor chip 100 may be disposed on a center of each unit region 10U. A plurality of chip pads CP may be disposed on the bottom surface of the semiconductor chip 100. The semiconductor chip 100 may be placed to allow its bottom surface to face a top surface of the wiring substrate 10, and the chip pads CP of the semiconductor chip 100 may be connected to the upper wire patterns 121 of the wiring substrate 10. The connection terminals 150 may be attached between the chip pads CP of the semiconductor chip 100 and the upper wire patterns 121 of the wiring substrate 10.

An under fill layer UF may be provided in a gap between the wiring substrate 10 and the semiconductor chip 100, thereby encapsulating the connection terminals 150. The under fill layer UF may include or be formed of a dielectric polymer or a dielectric film. For example, the under fill layer UF may include an epoxy-based polymer.

The wiring substrate 10 may be provided thereon with the molding layer 200 that covers the semiconductor chip 100. The molding layer 200 may be in contact with the top surface of the first upper protection pattern SR1. The molding layer 200 may be provided on the top surface of the wiring substrate 10, and may cover a sidewall and a top surface of the semiconductor chip 100. The molding layer 200 may include a dielectric polymer, such as epoxy molding compound.

The external input/output terminals 250 may be attached to the lower wire patterns 123 of the wiring substrate 10. The external input/output terminals 250 may be solder balls or bumps.

According to some embodiments of the present inventive concepts, a wiring substrate may include a first upper protection pattern on a unit region, and may also include on an edge region a second upper protection pattern that is formed of a dielectric material different from that of the first upper protection pattern.

Therefore, in a molding process for a semiconductor package, a release film may be in contact with the second upper protection pattern whose adhesive force is low, and thus the release film may be prevented from being attached to the wiring substrate. In addition, the wiring substrate may be prevented from deformation or warpage due to detachment of the wiring substrate from a molding apparatus in the molding process, which detachment is caused by attachment of the release film to the wiring substrate.

Although the present inventive concepts have been described in connection with some embodiments of the present inventive concepts illustrated in the accompanying drawings, it will be understood to those skilled in the art that various changes and modifications may be made without departing from the technical spirit and essential feature of the present inventive concepts. It will be apparent to those skilled in the art that various substitution, modifications, and changes may be thereto without departing from the scope and spirit of the present inventive concepts. Accordingly, all such modifications are intended to be included within the scope of the present disclosure as defined in the appended claims.

What is claimed is:

1. A wiring substrate, comprising:
a dielectric layer that includes a plurality of unit regions, a sawing region that surrounds each of the unit regions, and an edge region that surrounds the unit regions and the sawing region;
a first upper protection pattern on a top surface of the dielectric layer on the unit regions and the sawing region; and
a second upper protection pattern on a top surface of the dielectric layer on the edge region,
wherein the second upper protection pattern surrounds the first upper protection pattern when viewed in plan and includes a dielectric material different from a dielectric material of the first upper protection pattern.

2. The wiring substrate of claim 1, wherein the first upper protection pattern covers the unit regions and the sawing region.

3. The wiring substrate of claim 1, further comprising:
a plurality of upper wire patterns on the top surface of the dielectric layer on each of the unit regions,
wherein the upper wire patterns are surrounded by the second upper protection pattern.

4. The wiring substrate of claim 1, wherein each of the first and second upper protection patterns is formed of a dielectric material including fillers, and
wherein a content of the fillers in the first upper protection pattern is different from a content of the fillers in the second upper protection pattern.

5. The wiring substrate of claim 4, wherein the dielectric material includes a solder resist.

6. The wiring substrate of claim 4, wherein the fillers include silicon oxide (SiO₂).

7. The wiring substrate of claim 1, wherein the second upper protection pattern includes a material whose adhesive force is less than an adhesive force of the first upper protection pattern.

8. The wiring substrate of claim 1, wherein the first and second upper protection patterns have a thickness of about 10 μm to about 20 μm.

9. The wiring substrate of claim 1, wherein the dielectric layer has a thickness of about 20 μm to about 100 μm.

10. The wiring substrate of claim 1, further comprising:
a plurality of lower wire patterns on a bottom surface of the dielectric layer on each of the unit regions; and
a lower protection layer on a bottom surface of the dielectric layer on the unit regions and the sawing region,
wherein the lower protection layer includes a dielectric material the same as a dielectric material of the first upper protection pattern.

11. A method of fabricating a wiring substrate, the method comprising:
providing a panel substrate that includes a plurality of substrate regions and a cutting region that surrounds each of the substrate regions;
forming a first upper protection layer on a top surface of the panel substrate;
patterning the first upper protection layer to form an opening that exposes the top surface of the panel substrate on the cutting region;
forming a second upper protection pattern in the opening; and
forming a wiring substrate by cutting the panel substrate along the cutting region to separate the substrate regions from each other,
wherein the second upper protection pattern includes a dielectric material different from a dielectric material of the first upper protection layer.

12. The method of claim 11, wherein each of the substrate regions includes a plurality of unit regions and a sawing region that surrounds each of the unit regions, and
wherein the first upper protection layer covers the unit regions and the sawing region on each of the substrate regions.

13. The method of claim 11, wherein the second upper protection pattern includes a material whose adhesive force is less than an adhesive force of the first upper protection layer.

14. The method of claim 11, wherein the patterning of the first upper protection layer includes forming a plurality of first upper protection patterns that respectively correspond to the substrate regions, and
wherein, when viewed in plan, the second upper protection pattern surrounds each of the first upper protection patterns.

15. The method of claim 14, wherein each of the first and second upper protection patterns is formed of a dielectric material including fillers, and
wherein a content of the fillers in each of the first upper protection patterns is different from a content of the fillers in the second upper protection pattern.

16. The method of claim 15, wherein the fillers include silicon oxide (SiO₂).

17. The method of claim 15, wherein the content of the fillers in each of the first upper protection patterns is greater than the content of the fillers in the second upper protection pattern.

18. A method of fabricating a semiconductor package, the method comprising:
providing a wiring substrate that has a plurality of unit regions, a sawing region that surrounds each of the unit regions, and an edge region that surrounds the unit regions and the sawing region;
mounting a plurality of semiconductor chips on corresponding unit regions of the wiring substrate;
forming on the wiring substrate a molding layer that covers the semiconductor chips; and
after forming the molding layer, cutting the wiring substrate along the sawing region to separate the unit regions from each other on which the semiconductor chips are mounted,
wherein the providing of the wiring substrate includes:
forming a first upper protection pattern that covers the unit regions and the sawing region; and
forming a second upper protection pattern that surrounds the first upper protection pattern on the edge region, and
wherein the forming of the molding layer includes:
providing a cavity with the wiring substrate on which the semiconductor chips are mounted, the cavity being defined by an upper mold and a lower mold;
attaching a release film that covers a surface of the upper mold and contacts the second upper protection pattern of the wiring substrate; and
introducing a molding resin into the cavity.

19. The method of claim 18, wherein each of the first and second upper protection patterns is formed of a dielectric material including fillers, and
wherein a content of the fillers in the first upper protection pattern is different from a content of the fillers in the second upper protection pattern.

20. The method of claim 18, wherein the forming of the molding layer includes contacting the release film and the molding layer in the cavity.
